(19) United States
(12) Patent Application Publication
(10) Pub. No.: US 2016/0141368 A1
(43) Pub. Date: May 19, 2016

(54) TALL STRAINED HIGH PERCENTAGE SILICON-GERMANIUM FINS

(71) Applicant: GLOBALFOUNDRIES INC., Grand Cayman (KY)

(72) Inventors: Kangguo Cheng, Schenectady, NY (US); Ali Khakifirooz, Los Altos, CA (US); Alexander Reznicek, Troy, NY (US); Dominic Schepis, Wappingers Falls, NY (US)

(73) Assignee: GLOBALFOUNDRIES INC., Grand Cayman (KY)

(21) Appl. No.: 14/540,051

(22) Filed: Nov. 13, 2014

(51) Int. Cl. H01L 29/10; H01L 29/66; H01L 29/78; H01L 21/762; H01L 21/02

(52) U.S. Cl. CPC H01L 29/1054; H01L 21/76283; H01L 21/02123; H01L 29/7846; H01L 29/785; H01L 29/66795

(57) ABSTRACT

The present invention relates generally to semiconductor devices and more particularly, to a structure and method of forming one or more tall strained silicon germanium (SiGe) fins on a semiconductor on insulator (SOI) substrate. The fins have a germanium (Ge) concentration which may differ from the Ge concentration within the top layer of the SOI substrate. The difference in Ge concentration between the fins and the top layer of the SOI substrate may range from approximately 10 atomic percent to approximately 40 atomic percent. This Ge concentration differential may be used to tailor a strain on the fins. The strain on the fins may be tailored to increase the critical thickness and allow for a greater height of the fins as compared to conventional strained fins of the same SiGe concentration formed from bulk material.

### BACKGROUND

The present invention relates generally to semiconductor devices, and more particularly, to a structure and method for forming strained fin field effect transistor devices.

A fin field effect transistor (FinFET) provides solutions to metal-oxide-semiconductor field effect transistor (MOSFET) scaling problems at and below, for example, the 45 nm node of semiconductor technology. A FinFET comprises at least one narrow semiconductor fin (preferably <30 nm wide) gated on at least two sides. FinFET structures have conventionally been formed in either a semiconductor on insulator (SOI) substrate or a bulk semiconductor substrate.

In some FinFET devices, the introduction of stress (i.e., compressive or tensile) to the channel region of the FinFET may be used in order to improve carrier mobility, which may subsequently increase FinFET performance. Compressive strain may be used with p-channel FETs (PFETs) to improve hole mobility and tensile strain may be used with n-channel FETs (NFETs) to improve electron mobility. While a high strain level may lead to increased carrier mobility, only fairly thin layers of strained material may be achievable because relaxation and defect formation set in (i.e., critical thickness).

### SUMMARY

According to an embodiment, a method is disclosed. The method may include: forming a stressed silicon germanium (SiGe) layer on an upper surface of a semiconductor on insulator (SOI) substrate, the SOI substrate comprising a base substrate layer, an insulator layer on the base substrate layer, and a relaxed SiGe layer on the insulator layer, wherein the Ge concentration in the stressed SiGe layer may differ from the Ge concentration in the relaxed SiGe layer by approximately 10 atomic percent to approximately 40 atomic percent; and forming a fin from the stressed SiGe layer.

According to another embodiment, a method is disclosed. The method may include: forming a shallow trench isolation (STI) in a relaxed silicon germanium (SiGe) layer of a strained germanium on insulator (SGOI) substrate to isolate a first active region and a second active region, the SGOI substrate comprising a base substrate layer, an insulator layer on the base substrate layer, and the relaxed SiGe layer on the insulator layer; forming a first stressed SiGe layer on the first active region, wherein the Ge concentration in the first stressed SiGe layer may differ from the Ge concentration in the relaxed SiGe by approximately 10 atomic percent to approximately 40 atomic percent; forming a second stressed SiGe layer on the second active region, wherein the Ge concentration in the second stressed SiGe layer may differ from the Ge concentration in the relaxed SiGe by approximately 10 atomic percent to approximately 40 atomic percent; and forming one or more fins in the first stressed SiGe layer and the second stressed SiGe layer.

According to another embodiment, a structure is disclosed. The structure may include: a semiconductor on insulator (SOI) substrate, comprising a base substrate layer, an insulator layer on the base substrate layer, and a relaxed SiGe layer on the insulator layer; and one or more fins comprised of SiGe located on the relaxed SiGe layer, wherein the Ge concentration in the fins may differ from the Ge concentration in the relaxed SiGe layer by approximately 10 atomic percent to approximately 40 atomic percent.

### BRIEF DESCRIPTION OF THE SEVERAL VIEWS OF THE DRAWINGS

The following detailed description, given by way of example and not intended to limit the invention solely thereto, will best be appreciated in conjunction with the accompanying drawings, in which not all structures may be shown.

FIG. 1 is a cross section view illustrating a structure, according an embodiment of the present invention.

FIG. 2 is a cross section view illustrating forming a stressed SiGe layer, according an embodiment of the present invention.

FIG. 3A is a cross section view illustrating forming bottom connected compressive strained fins, according an embodiment of the present invention.

FIG. 3B is a cross section view illustrating forming isolated compressive strained fins, according an embodiment of the present invention.

FIG. 4A is a cross section view illustrating forming a dielectric material between the bottom connected compressive strained fins, according an embodiment of the present invention.

FIG. 4B is a cross section view illustrating forming a dielectric material between the isolated compressive strained fins, according an embodiment of the present invention.

FIG. 5 is a cross section view illustrating a structure, according an embodiment of the present invention.

FIG. 6 is a cross section view illustrating forming a stressed SiGe layer, according an embodiment of the present invention.

FIG. 7A is a cross section view illustrating forming bottom connected tensile strained fins, according an embodiment of the present invention.

FIG. 7B is a cross section view illustrating forming isolated tensile strained fins, according an embodiment of the present invention.

FIG. 8A is a cross section view illustrating forming a dielectric material between the bottom connected tensile strained fins, according an embodiment of the present invention.

FIG. 8B is a cross section view illustrating forming a dielectric material between the isolated tensile strained fins, according an embodiment of the present invention.

FIG. 9 is a cross section view illustrating a structure, according an embodiment of the present invention.

FIG. 10 is a cross section view illustrating forming a shallow trench isolation, according an embodiment of the present invention.

FIG. 11 is a cross section view illustrating forming a compressive strained SiGe layer, according an embodiment of the present invention.

FIG. 12 is a cross section view illustrating forming a tensile strained SiGe layer, according an embodiment of the present invention.

FIG. 13A is a cross section view illustrating forming bottom connected compressive strained fins and bottom connected tensile strained fins, according an embodiment of the present invention.

FIG. 13B is a cross section view illustrating forming deep compressive strained fins and deep tensile strained fins, according an embodiment of the present invention.

FIG. 14A is a cross section view illustrating forming a dielectric material between the bottom connected compressive strained fins and the bottom connected tensile strained fins, according an embodiment of the present invention.

FIG. 14B is a cross section view illustrating forming a dielectric material between the isolated compressive strained fins and the isolated tensile strained fins, according an embodiment of the present invention.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element such as a layer, region, or substrate is referred to as being “on”, “over”, “beneath”, “below”, or “under” another element, it may be present on or below the other element or intervening elements may also be present. In contrast, when an element is referred to as being “directly on”, “directly over”, “directly beneath”, “directly below”, or “directly contacting” another element, there may be no intervening elements present. Furthermore, the terminology used herein is for the purpose of describing particular embodiments only and is not intended to be limiting of the invention. As used herein, the singular forms “a,” “an,” and “the” are intended to include the plural forms as well, unless the context clearly indicates otherwise.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

The present invention relates generally to semiconductor devices and more particularly, to a structure and method of forming a tall SiGe fin in a fin field effect transistor (FinFET) device, having a high concentration of Ge that varies from the underlying semiconductor on insulator (SOI) layer to produce a strain on the tall SiGe fin.

Typically, electron and hole mobility may be increased by utilizing SiGe with a high concentration of Ge, increasing the cross-sectional area through which current travels, and by inducing a strain (e.g. tension or compression) on the fin. However, conventional high percentage Ge fins must remain below a certain fin height to avoid reaching the critical thickness where relaxation and defect formation occur, thus reducing the cross-sectional area achievable in the fin. Embodiments of the present invention may allow for the formation of a SiGe fin having increased fin height, above the critical thickness of a corresponding blanket SiGe layer on silicon, by utilizing the underlying SOI layer to tailor a Ge concentration differential which permits a desired fin height.

The terms “epitaxial growth and/or deposition” and “epitaxially formed and/or grown” are used throughout the present application to denote the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of a semiconductor material with sufficient energy to move around on the surface and orient themselves to the crystal arrangement of the atoms of the deposition surface. Therefore, an epitaxial semiconductor material that is formed by an epitaxial deposition process has the same crystalline characteristics as the deposition surface on which it is formed. The temperature for epitaxial deposition typically ranges from 550° C. to 90° C. Although higher temperature typically results in faster deposition, the faster deposition may result in crystal defects and film cracking.

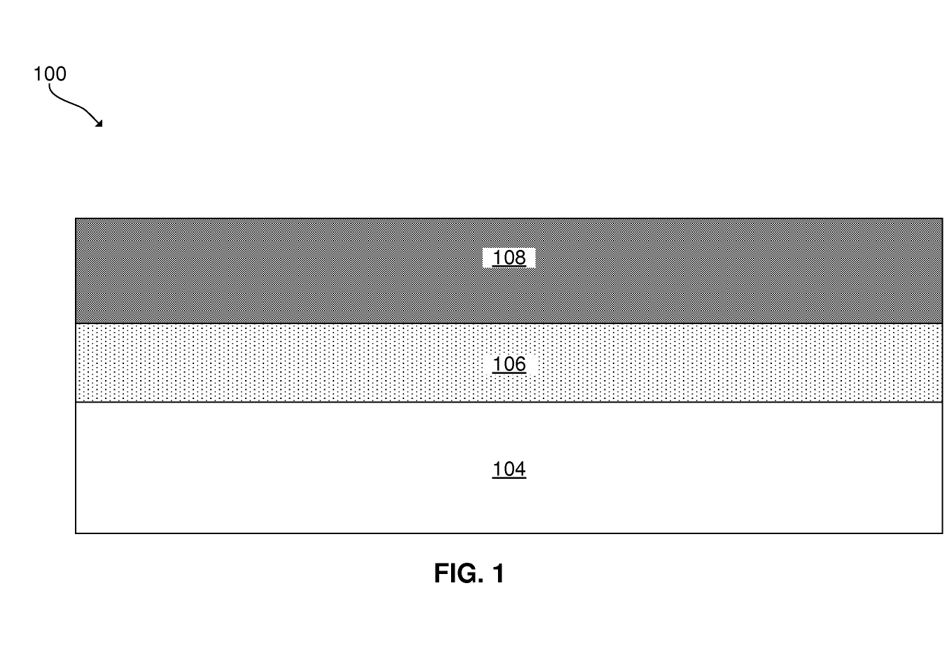

Methods of forming the tall fin comprised of SiGe with a high Ge concentration is described below with reference to FIGS. 1-14B. An embodiment by which to form a p-channel field effect transistor (PFET) device having tall strained SiGe fins is described below with reference to FIG. 1-4B.

Referring now to FIG. 1, a cross section view of a semiconductor on insulator (SOI) substrate 100 is shown. In an embodiment, the SOI substrate 100 may be a thermally mixed strained germanium on insulator (TMSGOI) substrate or a substrate fabricated by wafer bonding. The SOI substrate 100 may include a base substrate layer 104 separated from a SOI layer 108 by an insulator layer 106. In an embodiment, the SOI layer 108 may be composed of a relaxed semiconductor material, such as for example, silicon germanium (SiGe) with a Ge concentration ranging from approximately 40 atomic percent to approximately 60 atomic percent. In other words, the SOI substrate may be composed of Si₁₋ₓGeₓ where x may be between 0.4 and 0.6. In a preferred embodiment, the SOI layer 108 may have a Ge concentration of approximately 50 atomic percent. The insulator layer 106 may be composed of an insulating material, such as, for example, silicon dioxide (SiO₂).

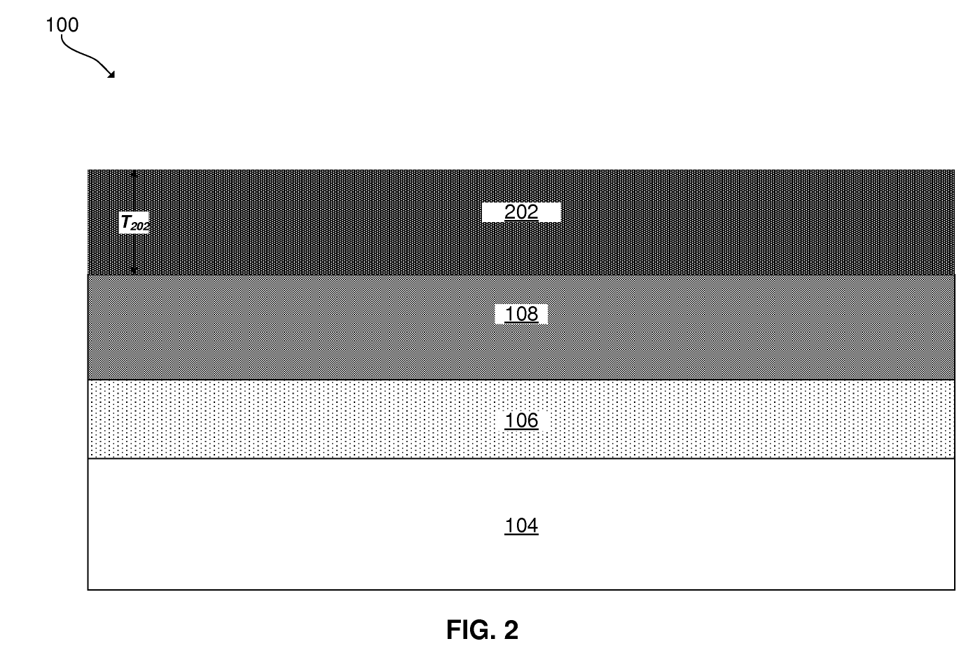

Referring now to FIG. 2, a cross section view illustrating forming a stressed SiGe layer 202 on the SOI substrate 100 is shown. The stressed SiGe layer 202 may have a thickness T₂₀₂ that ranges from approximately 20 nm to approximately 100 nm. The stressed SiGe layer 202 may be composed of SiGe with a Ge concentration ranging from approximately 50 atomic percent to approximately 100 atomic percent. In other words, the stressed SiGe layer 202 may be composed of Si_{1-y}Ge_{y} where y may be between 0.5 and 1. In a preferred embodiment, the stressed SiGe layer 202 may have a Ge concentration of approximately 75 atomic percent. The greater Ge concentration in the stressed SiGe layer 202 with respect to the SOI layer 108 may result in a compressive strain on the stressed SiGe layer 202. The compressive strain may be the result of a lattice mismatch between the stressed SiGe layer 202 and the SOI layer 108. In an embodiment the lattice mismatch may range from approximately 0% to approximately 2%. In a preferred embodiment, the lattice mismatch may be approximately 1%.

The stressed SiGe layer 202 may be formed on the SOI layer 108 using a conventional deposition process known in the art, such as, for example, rapid thermal chemical vapor deposition (RTCVD), low-energy plasma deposition (LEPD), ultra-high vacuum chemical vapor deposition (UHVCVD), or atmospheric pressure chemical vapor deposition (APCVD). In a preferred embodiment, the stressed SiGe layer 202 may be formed using a conventional epitaxial deposition process, such as molecular beam epitaxy (MBE).

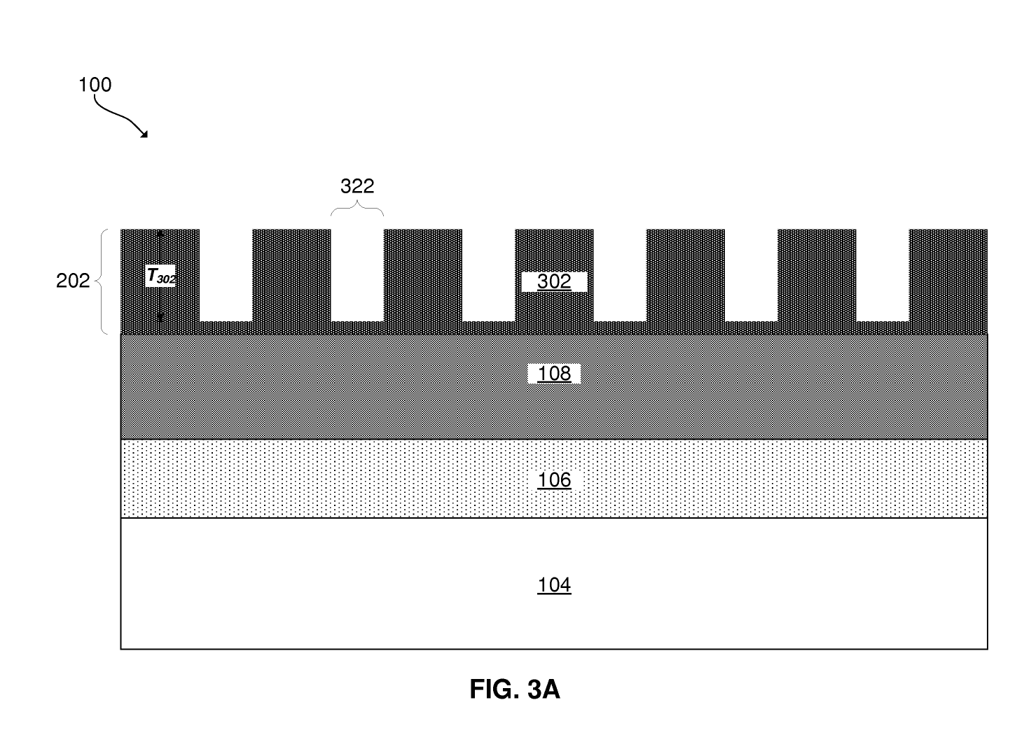

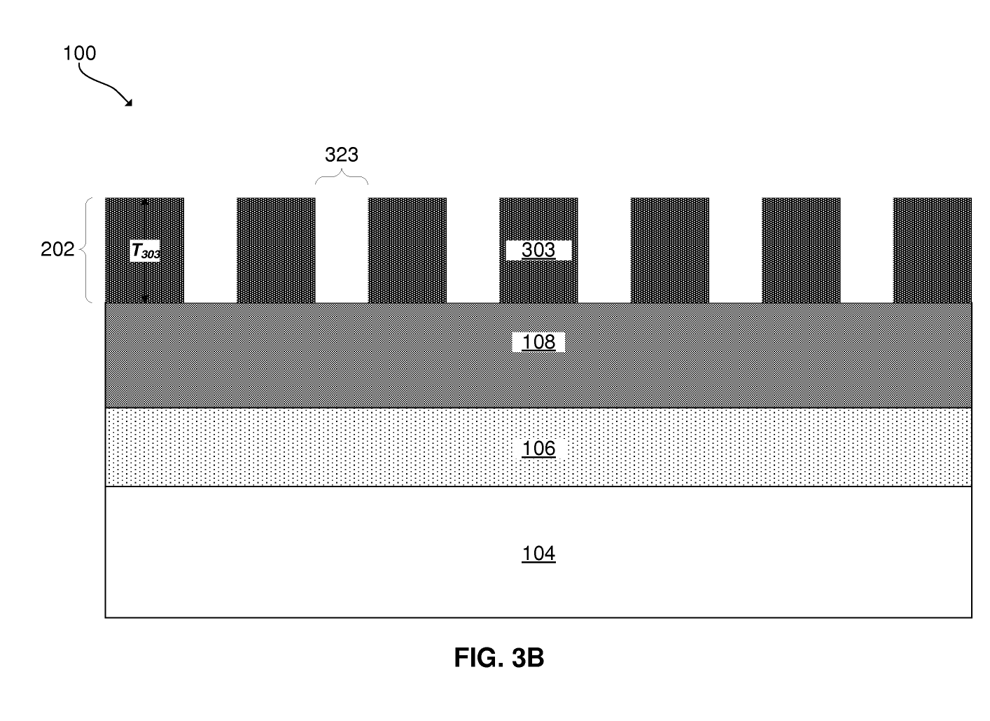

Referring now to FIGS. 3A-3B, cross section views illustrating forming fins in the stressed SiGe layer 202 to form PFET devices are shown. In an embodiment, as shown in FIG. 3A, one or more bottom connected fins 302 (hereinafter “bottom connected fins”) may be formed in the stressed SiGe layer 202. In another embodiment, as shown in FIG. 3B, one or more isolated fins 303 (hereinafter “isolated fins”) may be formed in the stressed SiGe layer 202. Because of the Ge concentration differential between the stressed SiGe layer 202 and the SOI layer 108, the bottom connected fins 302 and the isolated fins 303 may undergo a compressive strain which may enhance hole mobility and provide for a more effective PFET device.

The bottom connected fins 302 may be formed by removing a portion 322 of the stressed SiGe layer 202. The portion 322 may extend only partially through the depth of the stressed SiGe layer 202. The portion 322 may be removed using a conventional masking and etching process known in the art, such as, for example, timed reactive ion etching (RIE). In an embodiment, the portion 322 may be removed using sidewall image transfer (SIT). The bottom connected fins 302 may have a fin height T₃₀₂ ranging from approximately 20 nm to approximately 100 nm. The Ge concentration differential between the bottom connected fins 302 and the SOI layer 108 may increase the critical thickness and allow for a greater height of the bottom connected fins 302 as compared to conventional strained fins of the same SiGe concentration formed from bulk material. The large cross-sectional area of the bottom connected fins 302, due to the increased height, may increase current flow, which may increase device performance.

The isolated fins 303 may be formed by removing a portion 323 of the stressed SiGe layer 202. The portion 323 may extend through the entire depth of stressed SiGe layer 202 and may expose an upper surface of the SOI layer 108. The portion 323 may be removed using a conventional masking and etching process known in the art, such as, for example, RIE. In an embodiment, the portion 323 may be removed using SIT. The isolated fins 303 may have a fin height T₃₀₃ ranging from approximately 20 nm to approximately 100 nm. The Ge concentration differential between the isolated fins 303 and the SOI layer 108 may increase the critical thickness and allow for a greater height of the isolated fins 303 as compared to conventional strained fins of the same SiGe concentration formed from bulk material. The large cross-sectional area of the isolated fins 303, due to the increased height, may increase current flow, which may increase device performance.

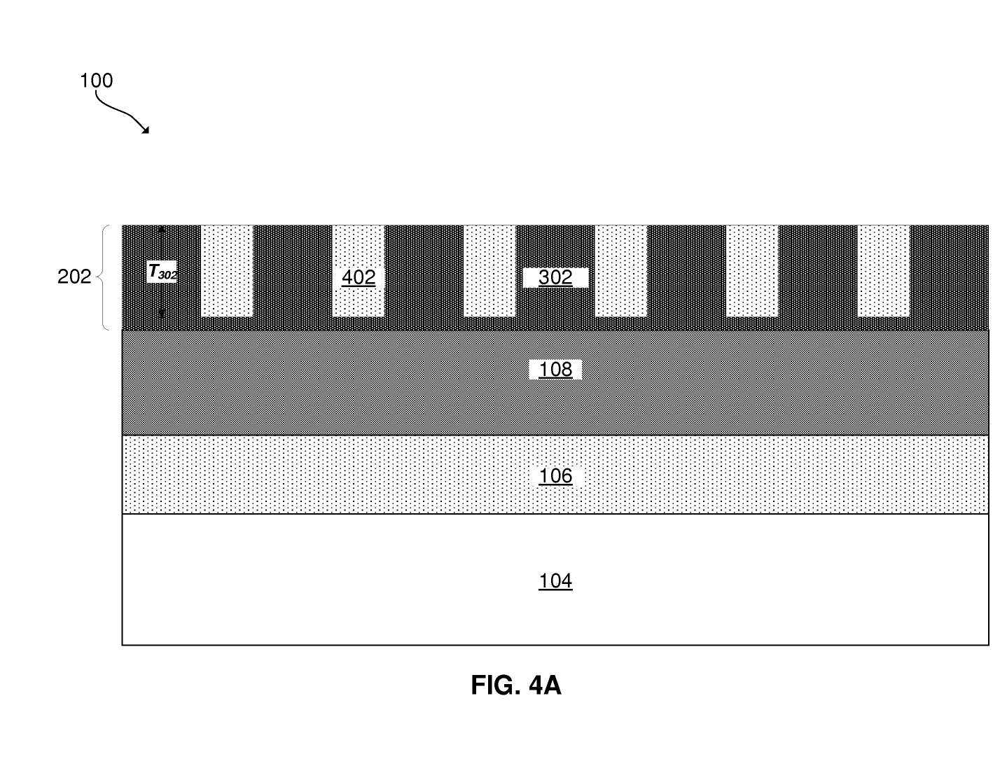

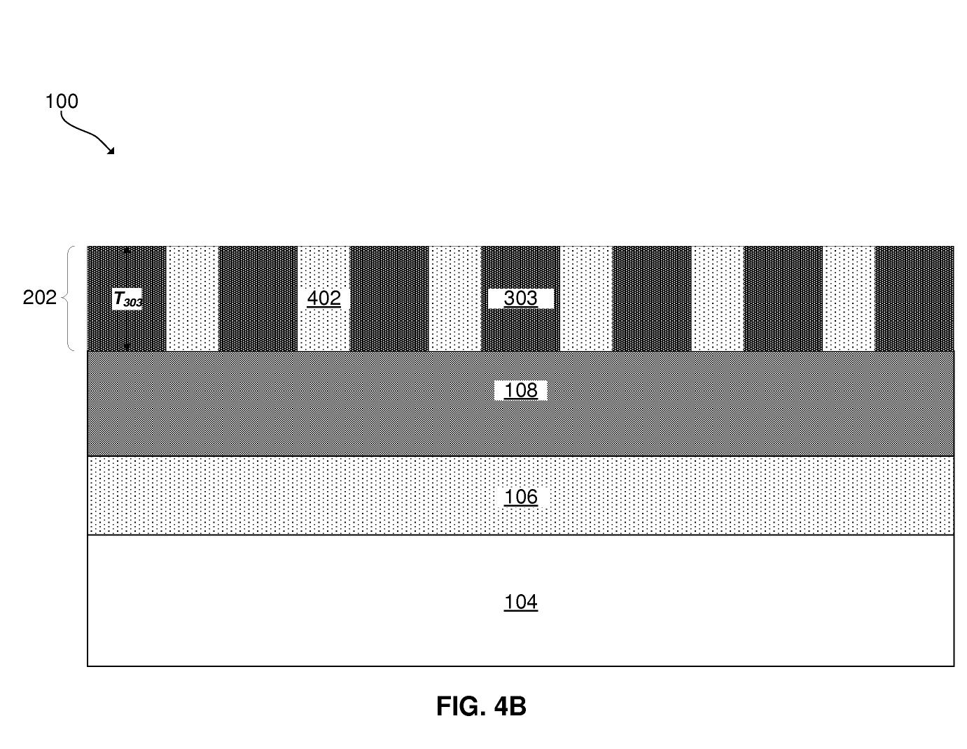

Referring now to FIGS. 4A-4B, cross section views illustrating forming one or more local isolation regions 402 (hereinafter “local isolation”) is shown. In an embodiment, as shown in FIG. 4A, the local isolation 402 may be formed in the portion 322 (FIG. 3A) between the bottom connected fins 302. In another embodiment, as shown in FIG. 4B, the local isolation 402 may be formed in the portion 323 (FIG. 3B) between the isolated fins 303. The local isolation 402 may be composed of a dielectric material, such as, for example, silicon dioxide (SiO₂).

The local isolation 402 may be formed using a conventional deposition technique, such as, for example, atomic layer deposition (ALD), chemical vapor deposition (CVD), physical vapor deposition (PVD), plasma enhanced CVD (PECVD), molecular beam deposition (MBD), pulsed laser deposition (PLD), liquid source misted chemical deposition (LSMCD), or spin on deposition. In an embodiment, the local isolation 402 may be planarized after deposition using a conventional technique, such as, for example, chemical mechanical planarization (CMP) such that an upper surface of the local isolation 402 is substantially flush with an upper surface of the bottom connected fins 302 or an upper surface of the isolated fins 303. In another embodiment, not shown, the local isolation 402 may be etched using a conventional technique, such as, for example, RIE so that an upper surface of the local isolation 402 is below an upper surface of the bottom connected fins 302 or an upper surface of the isolated fins 303.

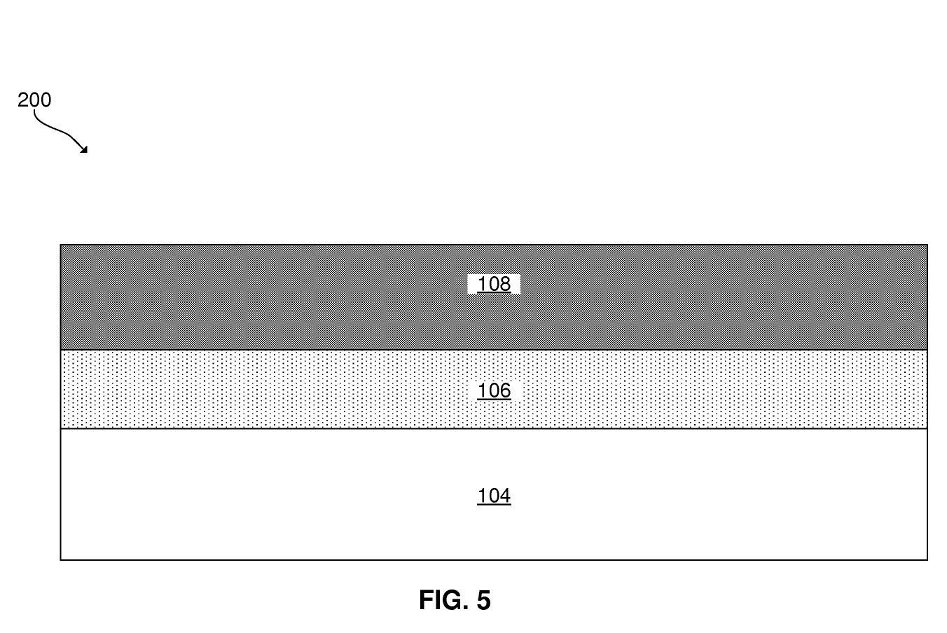

An embodiment by which to form a n-channel field effect transistor (NFET) device having tall strained SiGe fins is described below with reference to FIG. 5-8B.

Referring now to FIG. 5, a cross section view of a semiconductor on insulator (SOI) substrate 200 is shown. In an embodiment, the SOI substrate 200 may be a thermally mixed strained germanium on insulator (TMSGOI) substrate or a substrate fabricated by wafer bonding. The SOI substrate 200 may include a base substrate layer 104 separated from a SOI layer 108 by an insulator layer 106. In an embodiment, the SOI layer 108 may be composed of a relaxed semiconductor material, such as for example, silicon germanium (SiGe) with a Ge concentration ranging from approximately 40 atomic percent to approximately 60 atomic percent. In other words, the SOI substrate may be composed of Si₁₋ₓGeₓ where x may be between 0.4 and 0.6. In a preferred embodiment, the SOI layer 108 may have a Ge concentration of approximately 50 atomic percent. The insulator layer 106 may be composed of an insulating material, such as, for example, silicon dioxide (SiO₂).

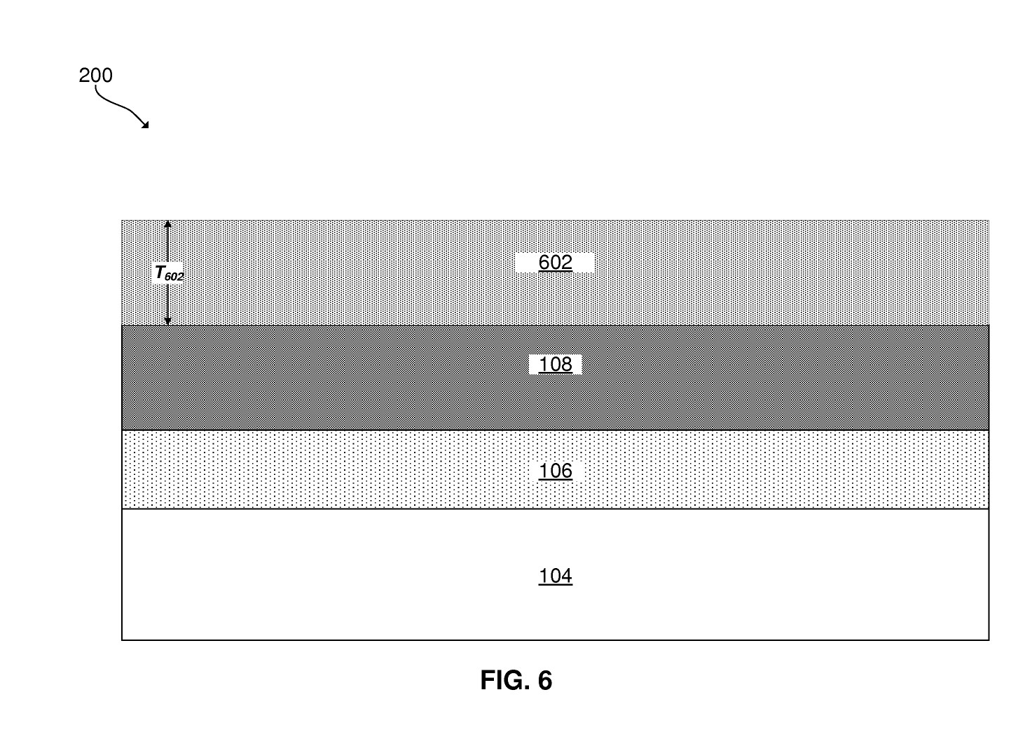

Referring now to FIG. 6, a cross section view illustrating forming a stressed SiGe layer 602 on the SOI substrate 200 is shown. The stressed SiGe layer 602 may have a thickness T₆₀₂ that ranges from approximately 20 nm to approximately 100 nm. The stressed SiGe layer 602 may be composed of SiGe with a Ge concentration ranging from approximately 0 atomic percent to approximately 50 atomic percent. In other words, the stressed SiGe layer 602 may be composed of Si_{1-y}Ge_{y} where y may be between 0 and 0.5. In a preferred embodiment, the stressed SiGe layer 602 may have a Ge concentration of approximately 25 atomic percent. The lower Ge concentration in the stressed SiGe layer 602 with respect to the SOI layer 108 may result in a tensile strain on the stressed SiGe layer 602. The tensile strain may be a result of a lattice mismatch between the stressed SiGe layer 602 and the SOI layer 108. In an embodiment, the lattice mismatch may range from approximately 0% to approximately 2%. In a preferred embodiment, the lattice mismatch may be approximately 1%.

The stressed SiGe layer 602 may be formed on the SOI layer 108 using a conventional deposition technique, such as, for example, RTCVD, LEPD, UHVCVD, and APCVD. In a preferred embodiment, the stressed SiGe layer 602 may be formed using a conventional epitaxial deposition process, such as MBE.

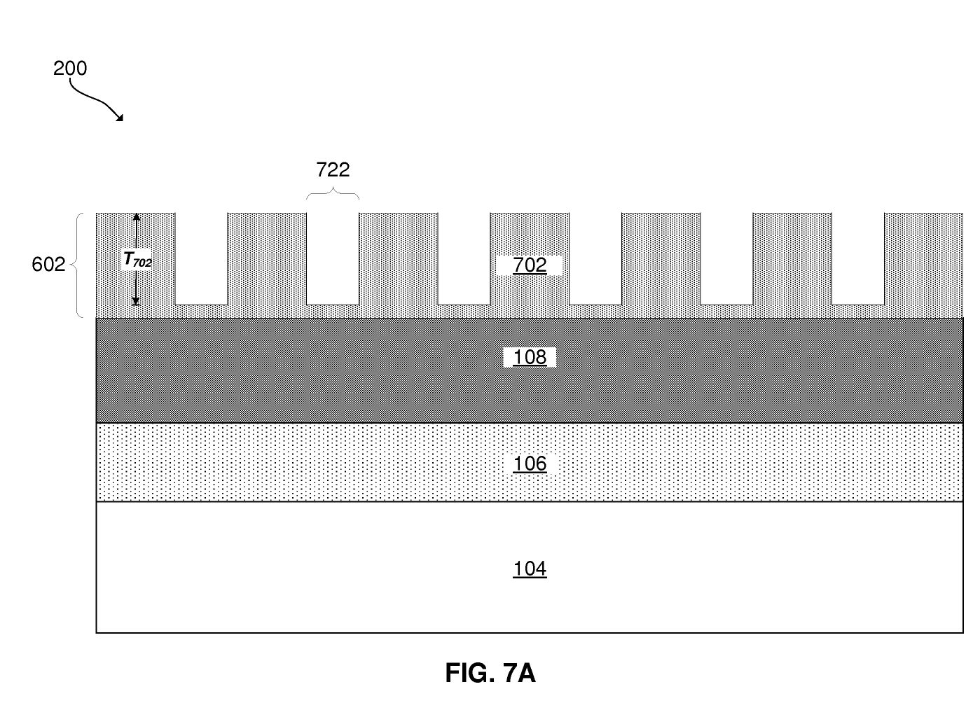

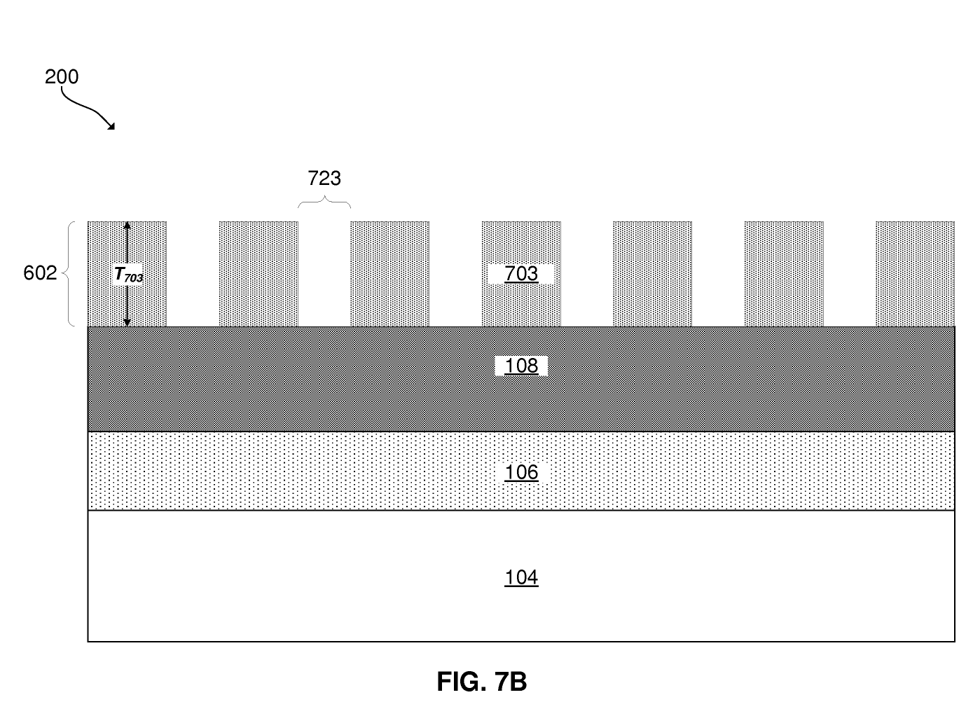

Referring now to FIGS. 7A-7B, cross section views illustrating forming fins in the stressed SiGe layer 602 to form NFET devices are shown. In an embodiment, as shown in FIG. 7A, one or more bottom connected fins 702 (hereinafter “bottom connected fins”) may be formed in the stressed SiGe layer 602. In another embodiment, as shown in FIG. 7B, one or more isolated fins 703 (hereinafter “isolated fins”) may be formed in the stressed SiGe layer 602. Because of the Ge concentration difference between the stressed SiGe layer 602 and the SOI layer 108, the bottom connected fins 702 and the isolated fins 703 may undergo a tensile strain which may enhance electron mobility and provide a more effective NFET device.

The bottom connected fins 702 may be formed by removing a portion 722 of the stressed SiGe layer 602. The portion 722 may extend only partially through the depth of the stressed SiGe layer 602. The portion 722 may be removed using a conventional masking and etching process known in the art, such as, for example, timed RIE. In an embodiment, the portion 722 may be removed using SIT. The bottom connected fins 702 may have a fin height T₇₀₂ ranging from approximately 20 nm to approximately 100 nm. The Ge concentration differential between the bottom connected fins 702 and the SOI layer 108 may increase the critical thickness and allow for a greater height of the bottom connected fins 702 as compared to conventional strained fins of the same SiGe concentration formed from bulk material. The large cross-sectional area of the bottom connected fins 702, due to the increased height, may increase current flow, which may increase device performance.

The isolated fins 703 may be formed by removing a portion 723 from the stressed SiGe layer 602. The portion 723 may extend through the entire depth of the stressed SiGe layer 602 and may expose an upper surface of the SOI layer 108. The portion 723 may be removed using a conventional masking and etching process known in the art, such as, for example, RIE. In an embodiment, the portion 723 may be removed using SIT. The isolated fins 703 may have a fin height T₇₀₃ ranging from approximately 20 nm to approximately 100 nm. The Ge concentration differential between the isolated fins 703 and the SOI layer 108 may increase the critical thickness and allow for a greater height of the isolated fins 703 as compared to conventional strained fins of the same SiGe concentration formed from bulk material. The large cross-sectional area of the isolated fins 703, due to the increased height, may increase current flow, which may increase device performance.

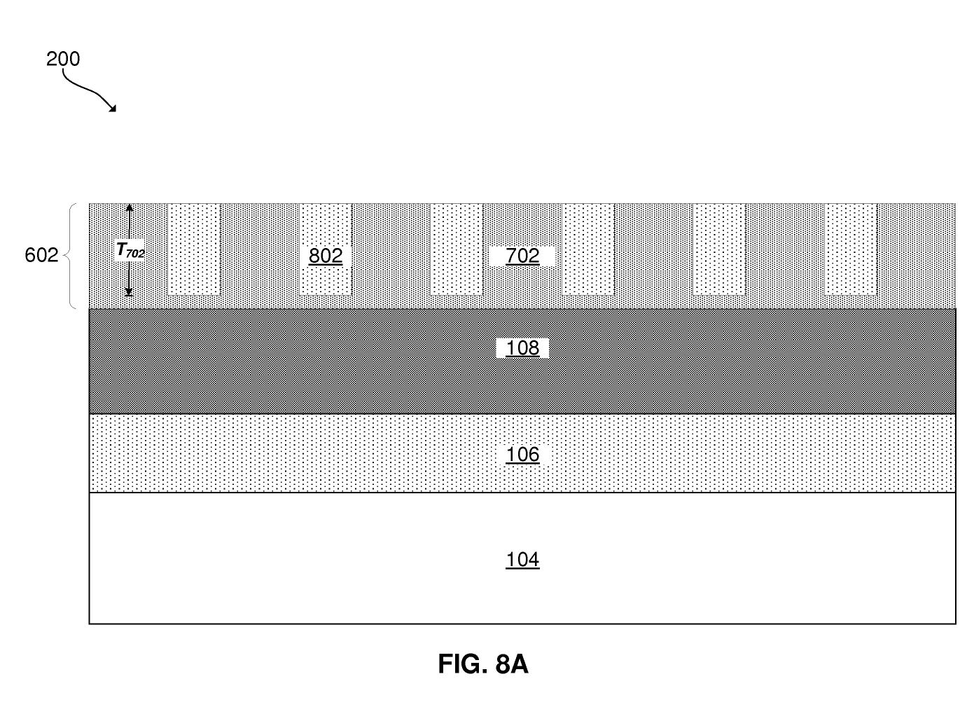

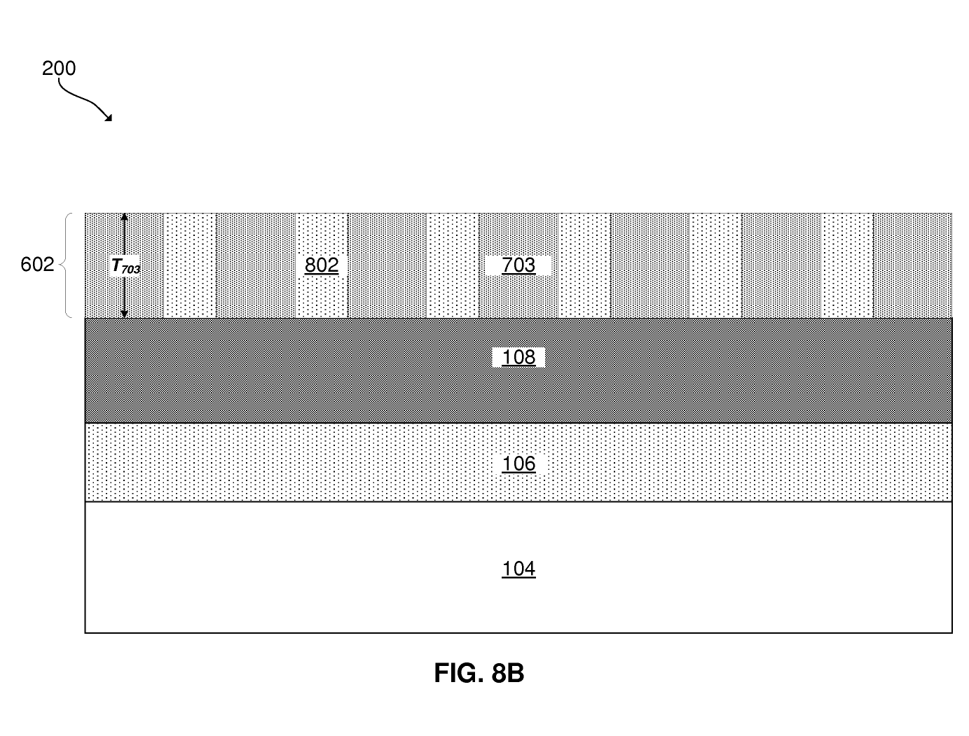

Referring now to FIGS. 8A-8B, cross section views illustrating forming one or more local isolation regions 802 (hereinafter “local isolation”) are shown. In an embodiment, as shown in FIG. 8A, the local isolation may be formed in the portion 722 (FIG. 7A) between the bottom connected fins 702. In another embodiment, as shown in FIG. 8B, the local isolation may be formed in the portion 723 (FIG. 7B) between the isolated fins 703. The local isolation 802 may be composed of a dielectric material, such as, for example, silicon dioxide (SiO₂).

The local isolation 802 may be formed using a conventional deposition technique, such as, for example, ALD, CVD, PVD, PECVD, MBD, PLD, LSMCD, or spin on deposition. In an embodiment, the local isolation 802 may be planarized after deposition using a conventional technique, such as, for example, chemical mechanical planarization (CMP) such that an upper surface of the local isolation 802 is substantially flush with an upper surface of the bottom connected fins 702 or an upper surface of the isolated fins 703. In another embodiment, not shown, the local isolation 802 may be etched using a conventional technique, such as, for example, RIE so that an upper surface of the local isolation 802 is below an upper surface of the bottom connected fins 702 or an upper surface of the isolated fins 703.

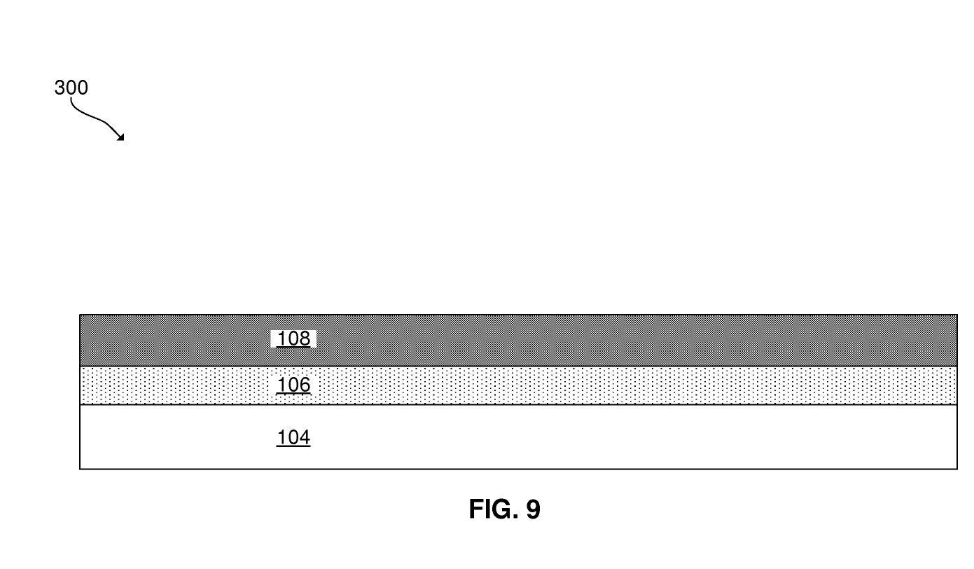

An embodiment by which to form a combination PFET and NFET device having tall strained SiGe fins is described below with reference to FIG. 9-14B.

Referring now to FIG. 9, a cross section view of a semiconductor on insulator (SOI) substrate 300 is shown. In an embodiment, the SOI substrate 300 may be a thermally mixed strained germanium on insulator (TMSGOI) substrate or a substrate fabricated by wafer bonding. The SOI substrate 300 may include a base substrate layer 104 separated from a SOI layer 108 by an insulator layer 106. In an embodiment, the SOI layer 108 may be composed of a relaxed semiconductor material, such as for example, silicon germanium (SiGe) with a Ge concentration ranging from approximately 40 atomic percent to approximately 60 atomic percent. In other words, the SOI layer 108 may be composed of Si₁₋ₓGeₓ where x may be between 0.4 and 0.6. In a preferred embodiment, the SOI layer 108 may have a Ge concentration of approximately 50 atomic percent. The insulator layer 106 may be composed of an insulating material, such as, for example, silicon dioxide (SiO₂).

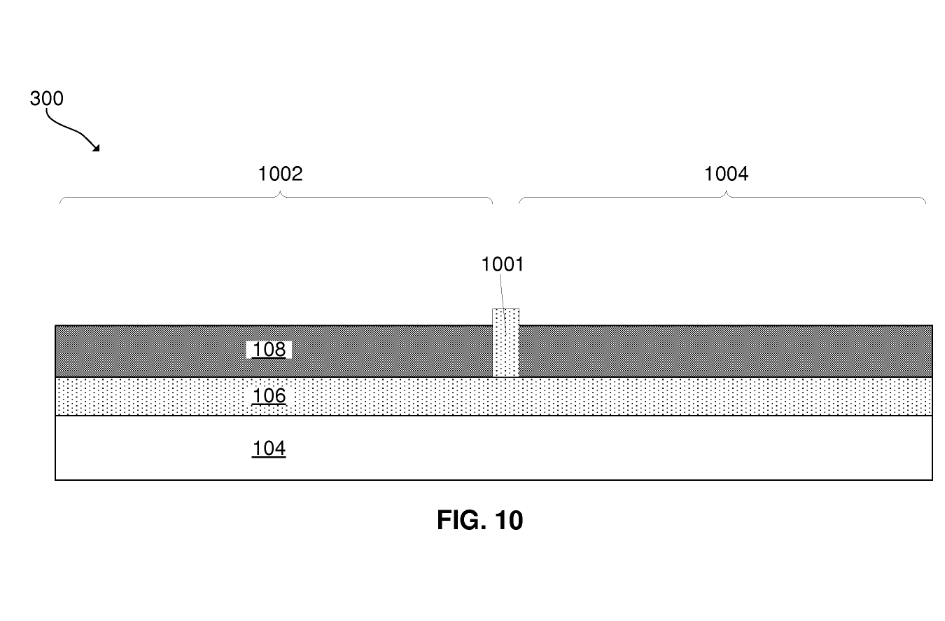

Referring now to FIG. 10, a cross section view illustrating forming a shallow trench isolation (STI) 1001 is shown. In order to form the STI 1001, a patterning layer (not shown) may be formed over the SOI layer 108. Subsequently, a portion of the patterning layer and a portion of the SOI layer 108 may be removed using a conventional etching process, such as, for example, RIE. In an embodiment, the opening may expose an upper surface of the insulator layer 106. The opening may be filled with a dielectric material, such as, for example, silicon dioxide (SiO₂) to form the STI 1001. After the STI 1001 is formed, the patterning layer may be removed. The STI 1001 may define a first active region 1002 and a second active region 1004 by electrically isolating each active area from the other.

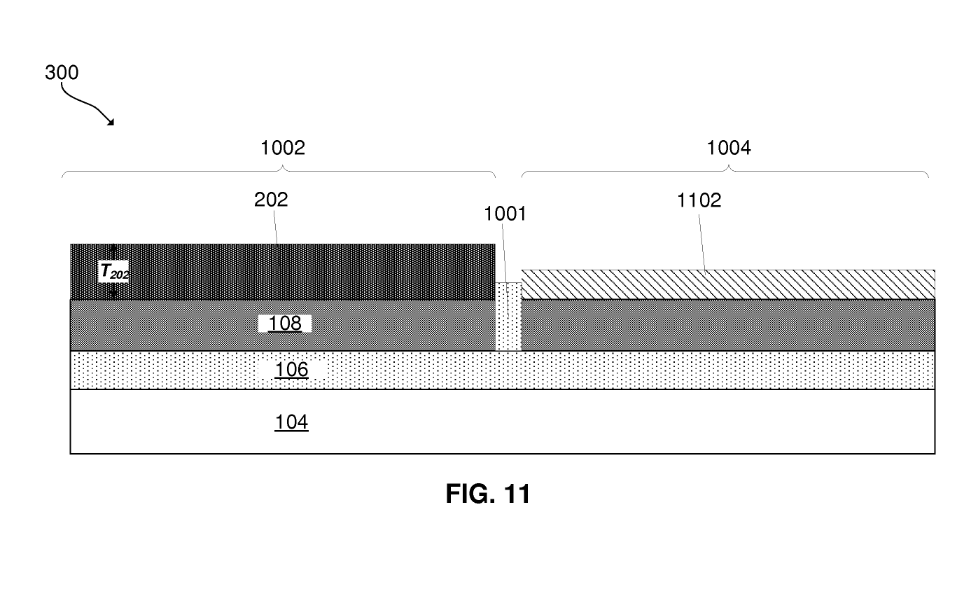

Referring now to FIG. 11, a cross section view illustrating forming the stressed SiGe layer 202 in the first active region 1002 is shown. In order to form the stressed SiGe layer 202 on only the first active region 1002, a hard mask 1102 may be first formed on the second active region 1004. After the hard mask 1102 is formed, the stressed SiGe layer 202 may be formed on the exposed SOI layer 108 in the first active region 1002 using a conventional deposition technique, such as, for example, RTCVD, LEPD, UHVCVD, or APCVD. In a preferred embodiment, the stressed SiGe layer 202 may be formed using a conventional epitaxial deposition process, such as MBE. After forming the stressed SiGe layer 202, the hard mask 1102 may be removed using a conventional etching process that is selective to the SOI layer 108, the STI 1001 and the stressed SiGe layer 202, such as, for example, RIE.

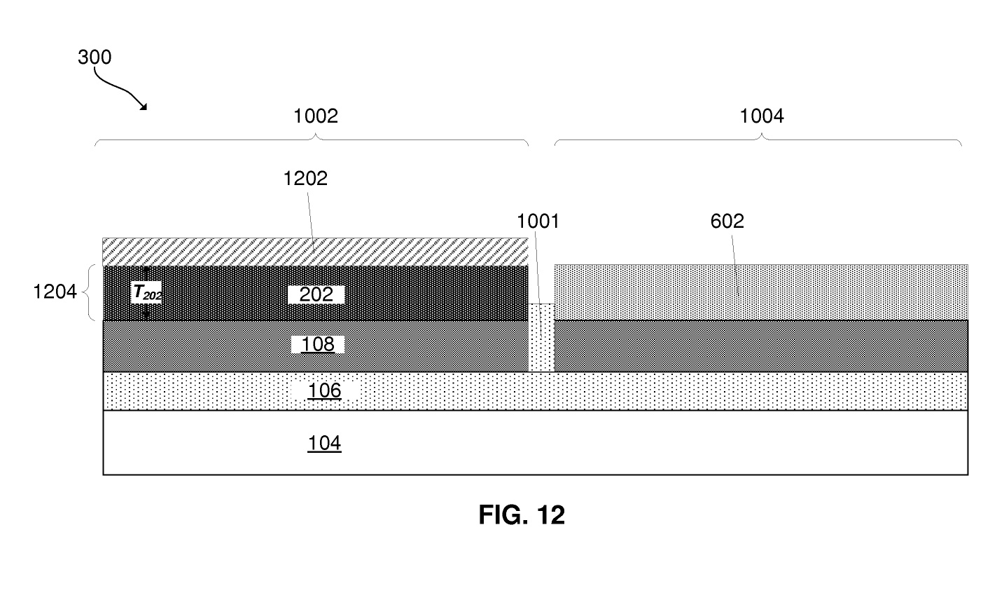

Referring now to FIG. 12, a cross section view illustrating forming the stressed SiGe layer 602 in the second active region 1004 is shown. In order to form the stressed SiGe layer 602 only on the second active region 1004, a hard mask 1202 may be first formed on the stressed SiGe layer 202. After the hard mask 1202 is formed, the stressed SiGe layer 602 may be formed on the exposed SOI layer 108 in the second active region 1004 using a conventional deposition technique, such as, for example, RTCVD, LEPD, UHVCVD, or APCVD. In a preferred embodiment, the stressed SiGe layer 602 may be formed using a conventional epitaxial deposition process, such as MBE. After forming the stressed SiGe layer 602, the hard mask 1202 may be removed using a conventional etching process that is selective to the SOI layer 108, STI 1001 and the stressed SiGe layer 602, such as, for example, RIE. The stressed SiGe layer 202 and the stressed SiGe layer 602 may have substantially similar heights, and may be collectively referred to as a hybrid layer 1204.

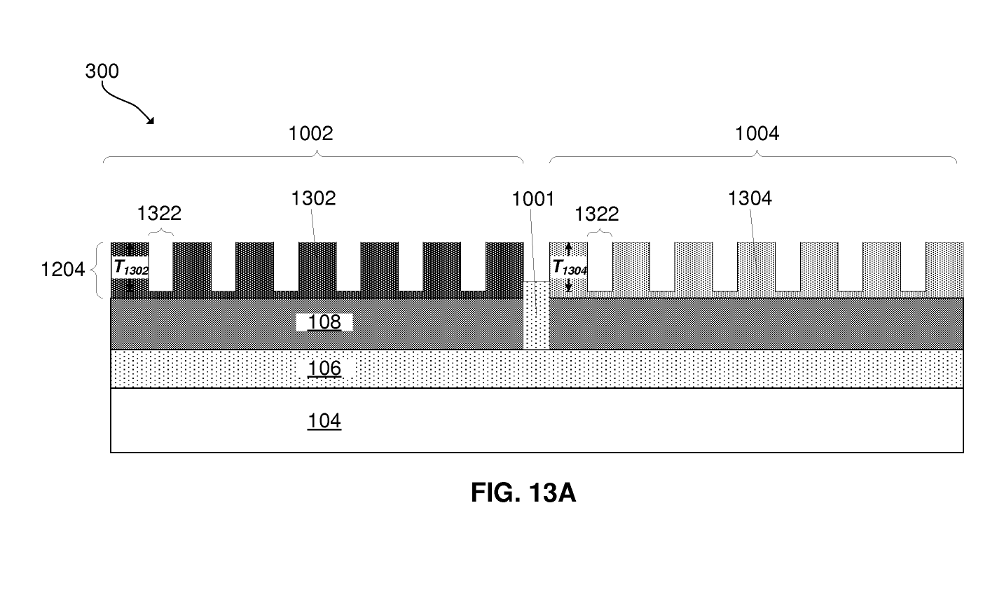

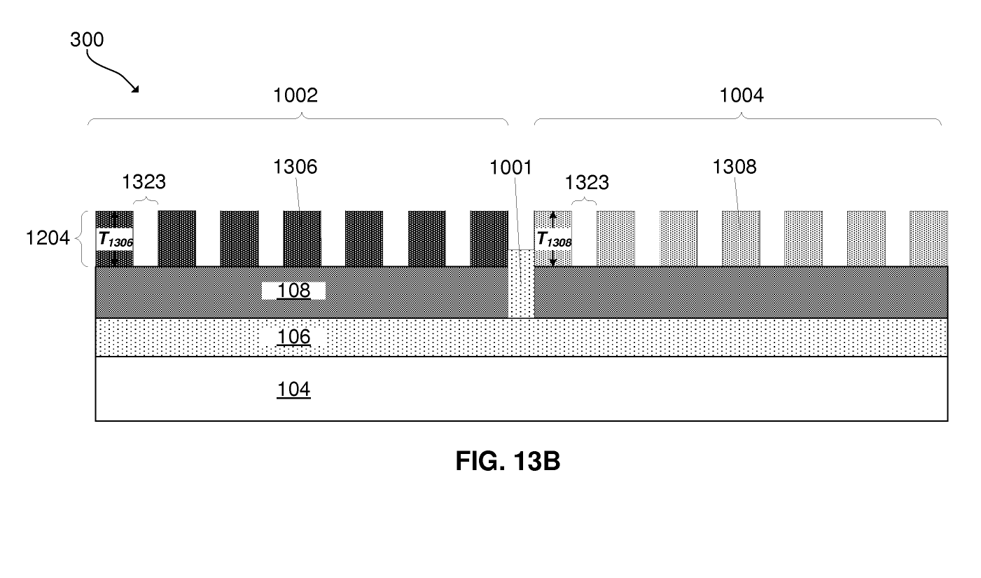

Referring now to FIGS. 13A-13B, cross section views illustrating forming fins in the hybrid layer 1204 to form PFET devices in the first active region 1002 and NFET devices in the second active region 1004 are shown. In an embodiment, as shown in FIG. 13A, one or more bottom connected fins 1302 (hereinafter “bottom connected fins”) may be formed in the first active region 1002 and one or more bottom connected fins 1304 (hereinafter “bottom connected fins”) may be formed in the second active region 1004. In another embodiment, as shown in FIG. 13B, one or more isolated fins 1306 (hereinafter “isolated fins”) may be formed in the first active region 1002 and one or more isolated fins 1308 (hereinafter “bottom connected fins”) may be formed in the second active region 1004.

Because of the Ge concentration difference between the first active region 1002 and the SOI layer 108, the bottom connected fins 1302 and the isolated fins 1306 may undergo a compressive strain which may enhance hole mobility and provide a more effective PFET device. In addition, because of the Ge concentration difference between the second active region 1004 and the SOI layer 108, the bottom connected fins 1304 and the isolated fins 1308 may undergo a tensile strain which may enhance electron mobility and provide a more effective NFET device.

As shown in FIG. 13A, the bottom connected fins 1302 and the bottom connected fins 1304 may be formed by removing a portion 1322 from the hybrid layer 1204. The portion 1322 and may extend only partially through the depth of the hybrid layer 1204. The portion 1322 may be removed using a conventional masking and etching process known in the art, such as, for example, timed RIE. In an embodiment, the portion 1322 may be removed using SIT.

The bottom connected fins 1302 may have a fin height T₁₃₀₂ ranging from approximately 20 nm to approximately 100 nm. The Ge concentration differential between the bottom connected fins 1302 and the SOI layer 108 may increase the critical thickness and allow for a greater height of the bottom connected fins 1302 as compared to conventional strained fins of the same SiGe concentration formed from bulk material. The large cross-sectional area of the bottom connected fins 1302, due to the increased height, may increase current flow, which may increase device performance.

The bottom connected fins 1304 may have a fin height T₁₃₀₄ ranging from approximately 20 nm to approximately 100 nm. The Ge concentration differential between the bottom connected fins 1304 and the SOI layer 108 may increase the critical thickness and allow for a greater height of the bottom connected fins 1304 as compared to conventional strained fins of the same SiGe concentration formed from bulk material. The large cross-sectional area of the bottom connected fins 1304, due to the increased height, may increase current flow, which may increase device performance.

As shown in FIG. 13B, the isolated fins 1306 and the isolated fins 1308 may be formed by removing a portion 1323 from the hybrid layer 1204. The portion 1323 may extend through the entire depth of the hybrid layer 1204 and may expose an upper surface of the SOI layer 108. The portion 1323 may be removed using a conventional masking and etching process known in the art, such as, for example, RIE. In an embodiment, the portion 1323 may be removed using SIT.

The isolated fins 1306 may have a fin height T₁₃₀₆ ranging from approximately 20 nm to approximately 100 nm. The Ge concentration differential between the isolated fins 1306 and the SOI layer 108 may increase the critical thickness and allow for a greater height of the isolated fins 1306 as compared to conventional strained fins of the same SiGe concentration formed from bulk material. The large cross-sectional area of the isolated fins 1306, due to the increased height, may increase current flow, which may increase device performance.

The isolated fins 1308 may have a fin height T₁₃₀₈ ranging from approximately 20 nm to approximately 100 nm. The Ge concentration differential between the isolated fins 1308 and the SOI layer 108 may increase the critical thickness and allow for a greater height of the isolated fins 1308 as compared to conventional strained fins of the same SiGe concentration formed from bulk material. The large cross-sectional area of the isolated fins 1308, due to the increased height, may increase current flow, which may increase device performance.

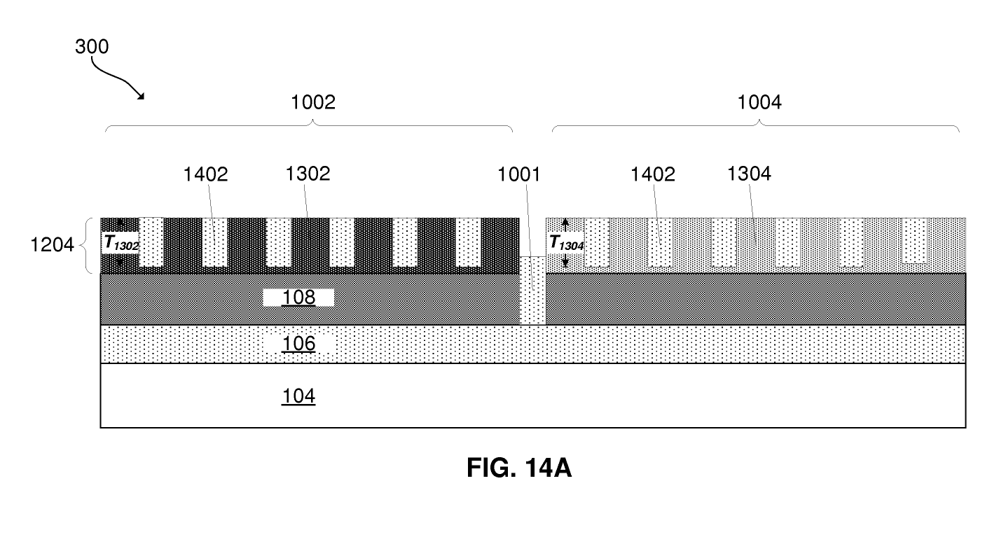

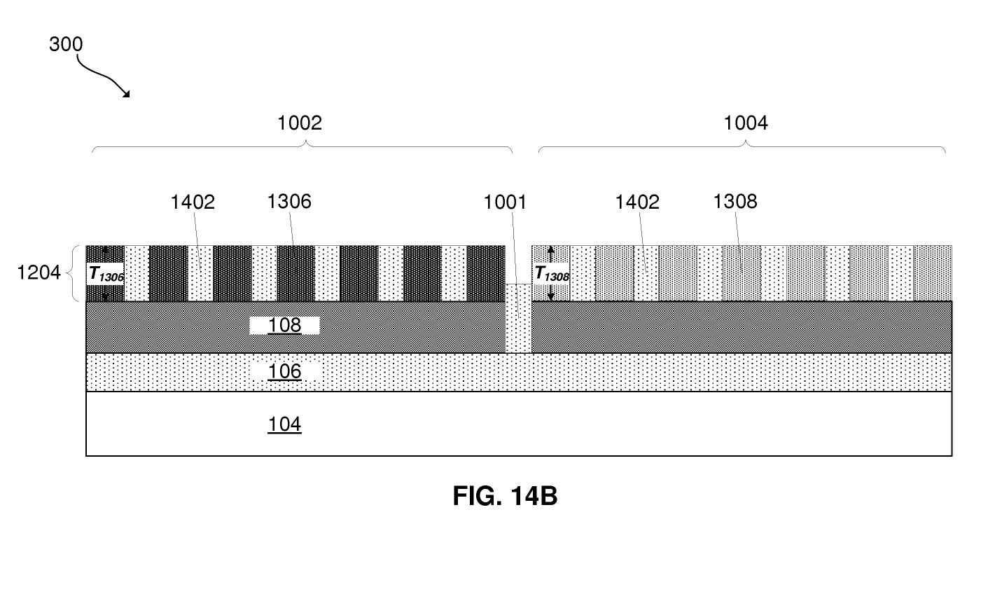

Referring now to FIGS. 14A-14B, cross section views illustrating forming one or more local isolation regions 1402 (hereinafter “local isolation”) are shown. In an embodiment, as shown in FIG. 14A, the local isolation 1402 may be formed in the portion 1322 (FIG. 13A) between the bottom connected fins 1302 and the bottom connected fins 1304. In another embodiment, as shown in FIG. 14B, the local isolation 1402 may be formed in the portion 1323 (FIG. 13B) between the isolated fins 1306 and the isolated fins 1308. The local isolation 1402 may be composed of a dielectric material, such as, for example, silicon dioxide (SiO₂).

The local isolation 1402 may be formed using a conventional deposition technique, such as, for example ALD, CVD, PVD, PECVD, MBD, PLD, LSMCD, or spin on deposition. In an embodiment, the local isolation 1402 may be planarized after deposition using a conventional technique, such as, for example, chemical mechanical planarization (CMP) such that an upper surface of the local isolation 1402 is substantially flush with an upper surface of the bottom connected fins 1302 and the bottom connected fins 1304. In another embodiment, the upper surface of the local isolation 1402 may be substantially flush with an upper surface of the isolated fins 1306 and the isolated fins 1308.

In another embodiment, not shown, the local isolation 1402 may be etched using a conventional technique, such as, for example, RIE so that an upper surface of the local isolation 1402 is below an upper surface of the bottom connected fins 1302 and the bottom connected fins 1304. In another embodiment, the upper surface of the local isolation 1402 may be below an upper surface of the isolated fins 1306 and the isolated fins 1308.

A tall strained fin NFET and a tall strained fin PFET may be utilized alone or in any combination. The bottom connected fins 1302 or the isolated fins 1306 may be utilized as a PFET alone or combined with a NFET device. The bottom connected fins 1304 or the isolated fins 1308 may be utilized as a NFET alone or combined with a PFET device.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

1. A method comprising:
forming a stressed silicon germanium (SiGe) layer on an upper surface of a semiconductor on insulator (SOI) substrate, the SOI substrate comprising a base substrate layer, an insulator layer on the base substrate layer, and a relaxed SiGe layer on the insulator layer, wherein a Ge concentration in the stressed SiGe layer may differ from a Ge concentration in the relaxed SiGe layer by approximately 10 atomic percent to approximately 40 atomic percent; and
forming a fin from the stressed SiGe layer,
wherein the relaxed SiGe layer includes SiGe having a Ge concentration ranging from approximately 40 atomic percent to approximately 60 atomic percent.

2. (canceled)

3. The method of claim 1, wherein the stressed SiGe layer comprises SiGe having a Ge concentration ranging from approximately 50 atomic percent to approximately 100 atomic percent.

4. The method of claim 1, wherein the stressed SiGe layer comprises SiGe having a Ge concentration ranging from approximately 0 atomic percent to approximately 50 atomic percent.

5. The method of claim 1, wherein the stressed SiGe layer has a thickness ranging from approximately 20 nm to approximately 100 nm.

6. The method of claim 1, wherein forming a fin from the stressed SiGe layer comprises:
removing a portion of the stressed SiGe layer such that a remaining portion of the stressed SiGe remains below the portion; and
forming an insulating region by filling the portion with a dielectric material.

7. The method of claim 1, wherein forming a fin from the stressed SiGe layer comprises:
removing a portion of the stressed SiGe layer such that an upper surface of the relaxed SiGe layer is exposed; and
forming an insulating region by filling the portion with a dielectric material.

8. A method comprising:
forming a shallow trench isolation (STI) in a relaxed silicon germanium (SiGe) layer of a strained germanium on insulator (SGOI) substrate to isolate a first active region and a second active region, the SGOI substrate comprising a base substrate layer, an insulator layer on the base substrate layer, and the relaxed SiGe layer on the insulator layer;
forming a first stressed SiGe layer on the first active region, wherein a Ge concentration in the first stressed SiGe layer may differ from a Ge concentration in the relaxed SiGe by approximately 10 atomic percent to approximately 40 atomic percent;
forming a second stressed SiGe layer on the second active region, wherein a Ge concentration in the second stressed SiGe layer may differ from a Ge concentration in the relaxed SiGe by approximately 10 atomic percent to approximately 40 atomic percent; and
forming one or more fins in the first stressed SiGe layer and the second stressed SiGe layer,
wherein the relaxed SiGe layer includes of SiGe having a Ge concentration of approximately 40 atomic percent to approximately 60 atomic percent.

9. (canceled)

10. The method of claim 8, wherein the first stressed SiGe layer comprises SiGe having a Ge concentration ranging from approximately 50 atomic percent to approximately 100 atomic percent, wherein a difference in Ge concentration in the first stressed SiGe layer and the relaxed SiGe layer induces a compressive stress on the first stressed SiGe layer.

11. The method of claim 8, wherein the second stressed SiGe layer comprises SiGe having a Ge concentration ranging from approximately 0 atomic percent to approximately 50 atomic percent, wherein a difference in Ge concentration in the second stressed SiGe layer and the relaxed SiGe layer induces a tensile stress on the second stressed SiGe layer.

12. The method of claim 8, further comprising forming a local isolation between the one or more fins, the local isolation layer having a bottom surface that is above a bottom surface of the one or more fins.

13. The method of claim 8, further comprising forming a local isolation between the one or more fins, the local isolation having a bottom surface that is substantially flush with a bottom surface of the one or more fins.

14. A structure comprising:
a semiconductor on insulator (SOI) substrate, comprising a base substrate layer, an insulator layer on the base substrate layer, and a relaxed silicon germanium (SiGe) layer on the insulator layer; and
one or more fins comprised of SiGe located on the relaxed SiGe layer, wherein a Ge concentration in the one or more fins may differ from the Ge concentration in the relaxed SiGe layer by approximately 10 atomic percent to approximately 40 atomic percent,
wherein the relaxed SiGe layer includes of SiGe having a Ge concentration ranging from approximately 40 atomic percent to approximately 60 atomic percent.

15. (canceled)

16. The structure of claim 14, wherein the one or more fins are comprised of SiGe having a Ge concentration of approximately 50 atomic percent to approximately 100 atomic percent.

17. The structure of claim 14, wherein the one or more fins are comprised of SiGe having a Ge concentration of approximately 0 atomic percent to approximately 50 atomic percent.

18. The structure of claim 14, further comprising a local isolation located between the one or more fins, the local isolation having a bottom surface that is above a bottom surface of the one or more fins.

19. The structure of claim 14, further comprising a local isolation located between the one or more fins, the local isolation having a bottom surface that is substantially flush with a bottom surface of the fins.

20. The structure of claim 14, further comprising a first active region and a second active region separated by a shallow trench isolation (STI), the STI extending through an entire thickness of the relaxed SiGe layer.
